(19) United States
(12) Patent Application Publication
(10) Pub. No.: US 2013/0344685 A1
(43) Pub. Date: Dec. 26, 2013

(54) PROCESSING METHOD AND PROCESSING APPARATUS

(71) Applicant: Disco Corporation, Tokyo (JP)

(72) Inventor: Keiji NOMARU, Tokyo (JP)

(21) Appl. No.: 13/926,437

(22) Filed: Jun. 25, 2013

(30) Foreign Application Priority Data
Jun. 25, 2012 (JP) 2012-142049

(51) Int. Cl. H01L 21/78

(52) U.S. Cl. CPC H01L 21/78
USPC 438/463; 156/345.5

(57) ABSTRACT

A processing method for etching a workpiece is disclosed. While etching gas is supplied into an etching chamber in which a workpiece held on a holding face of a holding table is accommodated, a laser beam of a wavelength having a transparency through the holding table and the workpiece is irradiated upon the workpiece from the opposite side to the holding face of the holding table such that the focal point of the laser beam is positioned in the inside of a processing region of the workpiece to excite the processing region to induce etching.

### BACKGROUND OF THE INVENTION

1. Field of the Invention

The present invention relates to a processing method and a processing apparatus for carrying out etching for a workpiece.

2. Description of the Related Art

In a semiconductor device fabrication process, the surface of a semiconductor wafer of a substantially disk shape is partitioned into a plurality of regions by division-scheduled lines called streets arrayed in a lattice pattern, and devices such as ICs or LSIs are formed in the partitioned regions. Then, the semiconductor wafer is cut along the streets to divide the regions in which the devices are formed from each other to produce individual semiconductor chips. Also an optical device wafer formed by laminating a gallium nitride-based compound semiconductor or the like on the surface of a sapphire substrate or a silicon carbide substrate is divided into the individual optical devices such as light emitting diodes or laser diodes by cutting the substrate along streets and the devices are utilized widely in electric apparatus.

The cutting of the wafer along the streets is carried out by a cutting apparatus called dicing saw. This cutting apparatus includes a chuck table for holding a workpiece such as a semiconductor wafer or an optical device wafer, cutting means for cutting the work held on the chuck table, and cutting feeding means for moving the chuck table and the cutting means relative to each other. The cutting means includes a spindle unit which in turn includes a rotary spindle, a cutting blade mounted on the spindle, and a driving mechanism for driving the rotary spindle to rotate. The cutting blade is configured from a base in the form of a disk, and an annular cutting edge mounted at an outer peripheral portion of a side face of the base. The cutting edge is formed with a thickness of approximately 30 μm by fixing diamond abrasive grain having a particle size of, for example, approximately 3 μm to the base by electrocasting. If such a cutting blade as just described is used to cut a wafer along streets to divide the wafer into individual devices, then there is a problem that chipping occurs with the front face and the rear face of the devices and degrades the flexural strength of the devices.

Meanwhile, as a method of dividing a wafer along streets, a method has been proposed wherein a pulsed laser beam of a wavelength having an absorbency by a wafer is irradiated along a street formed on the wafer to form a laser processed groove and the wafer is cut along the laser processed groove by a mechanical breaking apparatus (refer to, for example, Japanese Patent Laid-Open No. Hei 10-305420). However, if a pulsed laser beam of a wavelength having an absorbency by a wafer is irradiated along a street of the wafer, then this gives rise to a new problem that the thermal energy is concentrated upon an irradiate region to produce debris and the debris sticks to the surface of the devices and degrades the quality of the devices.

Further, as a method for dividing a wafer along a street, a laser processing method is attempted wherein a pulsed laser beam having a transparency through a wafer is used and irradiated from one face side of the wafer to a focal point in the inside of the wafer to continuously form a modified layer along a street in the inside of the wafer. Then, external force is applied along the street at which the strength is degraded by the formation of the modified layer to divide the wafer into individual devices (refer to, for example, Japanese Patent No. 3408805).

However, since the modified layer remains on a side face of the individual devices divided by the dividing method disclosed in Japanese Patent No. 3408805, there is a problem that the flexural strength of the devices degrades thereby to degrade the quality of the devices. In order to eliminate such a problem as just described, a technology has been proposed wherein solution for evaporating molten material of a workpiece is supplied to a processing object portion upon which a laser beam is irradiated so that the molten material scattered by the irradiation of the laser beam is evaporated (refer to, for example, Japanese Patent Laid-Open No. 2004-247426).

### SUMMARY OF THE INVENTION

However, the technology disclosed in Japanese Patent Laid-Open No. 2004-247426 has a problem that it is difficult to control the region to which solution for evaporating scattered molten material is to be supplied and this degrades the quality of devices.

Therefore, it is an object of the present invention to provide a processing method and a processing apparatus which can easily control a region to be processed.

In accordance with an aspect of the present invention, there is provided a processing method for a workpiece, including a holding step of holding a workpiece by a holding face of a holding table; a workpiece accommodation step of accommodating the workpiece held on the holding table into an etching chamber; an etching gas supplying step of supplying etching gas into the etching chamber after the workpiece accommodation step is carried out; and an etching induction step of irradiating, while the etching gas is being supplied, a laser beam of a wavelength having a transparency through the holding table and the workpiece from the opposite side to the holding face of the holding table such that a focal point of the laser beam is positioned in the inside of a processing region of the workpiece to excite the processing region to induce etching.

The processing region is a grooving region, and the laser beam is irradiated along the grooving region with the focal point thereof positioned in the inside of the grooving region of the workpiece. The workpiece is a silicon substrate, and the etching gas contains chlorine gas or chlorine trifluoride gas.

Further, in accordance with another aspect of the present invention, there is provided a processing apparatus for carrying out etching for a workpiece, including a holding table having a holding face for holding a workpiece; an etching chamber for accommodating a workpiece held on the holding face of the holding table; etching gas supplying means for supplying etching gas into the etching chamber; laser beam irradiation means disposed on the opposite side to the holding face of the holding table for irradiating a laser beam toward the workpiece held on the holding face of the holding table; and processing feeding means for feeding the holding table and the laser beam irradiation means relatively in a processing feeding direction for processing; the laser beam irradiation means being rendered operative, while the etching gas supplying means is rendered operative to supply the etching gas into the etching chamber, to irradiate a laser beam of a wavelength having a transparency through the holding table and the workpiece such that a focal point of the laser beam is positioned in the inside of a processing region of the workpiece to excite the processing region to induce etching.

In the present invention, while etching gas is supplied into the etching chamber in which a workpiece held on the holding face of the holding table is accommodated, a laser beam of a wavelength having a transparency through the holding table and the workpiece is irradiated upon the workpiece from the opposite side to the holding face of the holding table such that the focal point of the laser beam is positioned in the inside of the processing region of the workpiece to excite the processing region to induce etching. Therefore, the etched groove or the like does not at all suffer from production of a crack or a modified layer. Further, since the region to be etched is excited by the laser beam, the region to be processed can be controlled readily.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a processing apparatus configured in accordance with the present invention;

FIG. 2 is a sectional view of the processing apparatus shown in FIG. 1;

FIG. 3 is an exploded perspective view showing part of the processing apparatus shown in FIGS. 1 and 2;

FIG. 4 is a perspective view of a semiconductor wafer to be processed by a processing method according to the present invention;

FIGS. 5A and 5B are schematic views of a wafer supporting step of adhering the semiconductor wafer shown in FIG. 4 to the surface of a protective table mounted on an annular frame; and

FIGS. 6A to 6C are schematic views illustrating a processing step in the processing method according to the present invention.

### DETAILED DESCRIPTION OF THE PREFERRED EMBODIMENT

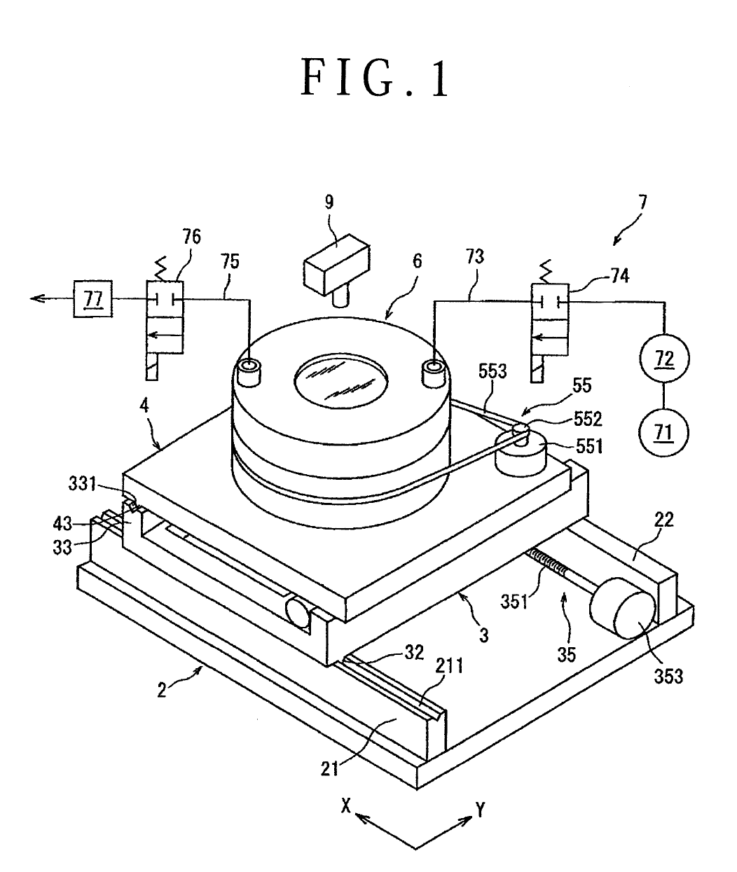

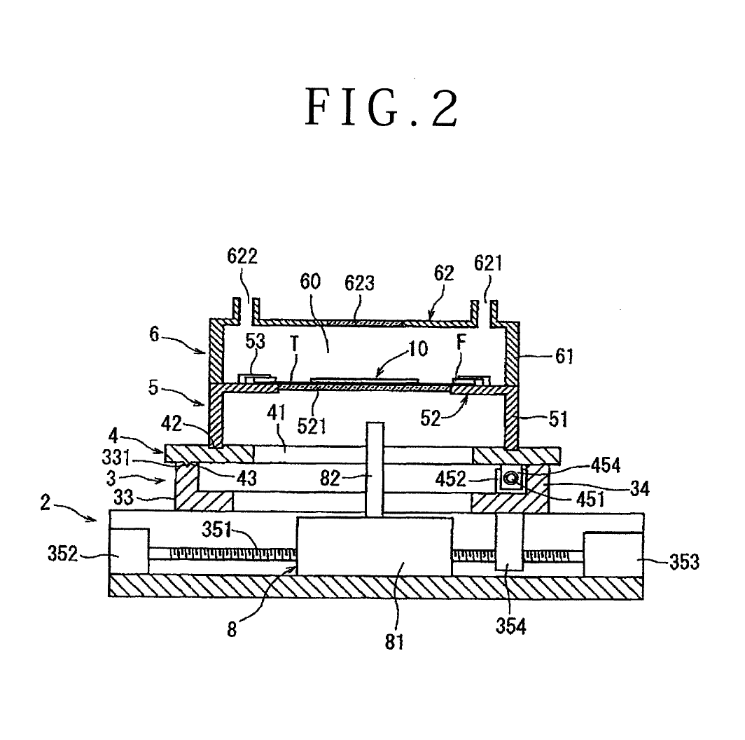

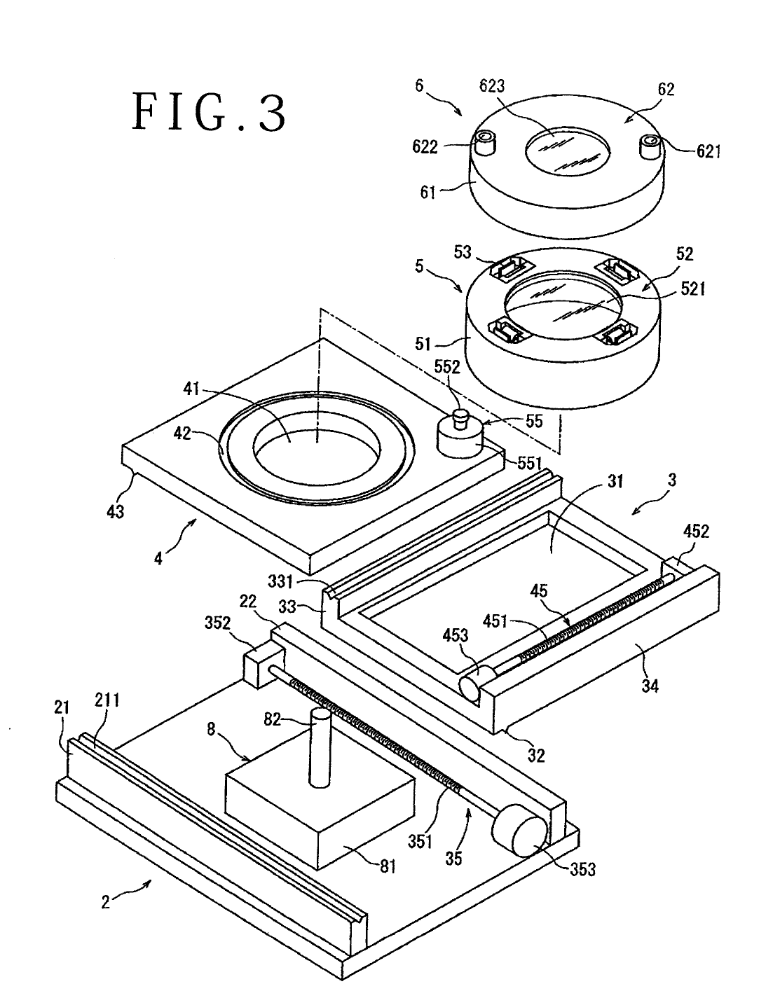

In the following, a preferred embodiment of a processing method and a processing apparatus according to the present invention is described in detail with reference to the accompanying drawings. FIG. 1 shows a perspective view of a processing apparatus configured in accordance with the present invention; FIG. 2 shows a sectional view of the processing apparatus shown in FIG. 1; and FIG. 3 shows an exploded perspective view showing part of the processing apparatus shown in FIGS. 1 and 2. The processing apparatus in the present embodiment includes a base 2, a first table 3 disposed on the base 2 for movement in a processing feeding direction indicated by an arrow mark X, and a second table 4 disposed for movement in an indexing feeding direction indicated by an arrow mark Y perpendicular to the arrow mark X on the first table 3. The base 2 is formed in a rectangular shape, and two guide rails 21 and 22 are disposed in parallel to each other in the processing feeding direction indicated by the arrow mark X on an upper face of the opposite side portions thereof. It is to be noted that, on an upper face of the one guide rail 21 from between the two guide rails, a guide groove 211 of a V-shaped cross section is formed.

The first table 3 is formed in the form of a window frame having a rectangular opening 31 provided at a central portion thereof as shown in FIG. 3. On a lower face of one side portion of the first table 3, a guided rail 32 for fitting for sliding moment in the guide groove 211 formed on the one guide rail 21 provided on the base 2 is provided. Meanwhile, on an upper face of the opposite side portions of the first table 3, two guide rails 33 and 34 are disposed in parallel to each other in a direction perpendicular to the guided rail 32. It is to be noted that a guide groove 331 having a V-shaped cross section is formed on an upper face of the one guide rail 33 from between the two guide rails. The first table 3 configured in this manner is fitted at the guided rail 32 thereof in the guide groove 211 formed on the guide rail 21 provided on the base 2 and is placed at a lower face of the other side portion thereof on the other guide rail 22 provided on the base 2 as shown in FIG. 1. The processing apparatus includes processing feeding means 35 for moving the first table 3 in the processing feeding direction indicated by the arrow mark X along the guide rails 21 and 22 provided on the base 2. This processing feeding means 35 is configured from a male thread rod 351 disposed in parallel to the other guide rail 22 provided on the base 2 as shown in FIG. 3, a bearing 352 disposed on the base 2 for supporting one end portion of the male thread rod 351 for rotation thereon, a pulse motor 353 connected to the other end of the male thread rod 351 for driving the male thread rod 351 to rotate, and a female thread block 354 provided on a lower face of the first table 3 as shown in FIG. 2 for being screwed with the male thread rod 351. In the processing feeding means 35 configured in this manner, the pulse motor 353 is driven to rotate the male thread rod 351 to move the first table 3 in the processing feeding direction indicated by the arrow mark X in FIG. 1.

The second table 4 is formed in a rectangular shape as shown in FIG. 3 and has a circular hole 41 at a central portion thereof and further has an annular fitting groove 42 provided on an upper face thereof which surrounds the circular hole 41. On a lower face of one side portion of the second table 4, a guided rail 43 is provided which fits for sliding movement in the guide groove 331 formed on the one guide rail 33 provided on the first table 3. The second table 4 configured in this manner is fitted at the guided rail 43 thereof in the guide groove 331 formed on the one guide rail 33 provided on the first table 3 as shown in FIG. 1 and is placed at a lower face of the other side portion thereof on the other guide rail 34 provided on the first table 3. The processing apparatus includes indexing feeding means 45 for moving the second table 4 in the indexing feeding direction indicated by the arrow mark Y along the guide rails 33 and 34 provided on the first table 3. This indexing feeding means 45 includes a male thread rod 451 disposed in parallel to the other guide rail 34 provided on the first table 3 as shown in FIG. 3, a bearing 452 disposed on the first table 3 for supporting one end portion of the male thread rod 451 for rotation thereon, a pulse motor 453 connected to the other end of the male thread rod 451 for driving the male thread rod 451 to rotate, and a female thread block 454 provided on the lower face of the second table 4 as shown in FIG. 2 for being screwed with the male thread rod 451. In the indexing feeding means 45 configured in this manner, the pulse motor 453 is driven to rotate the male thread rod 451 to move the second table 4 in the indexing feeding direction indicated by the arrow mark Y in FIG. 1.

The processing apparatus includes a holding table 5 disposed on the second table 4 for holding a workpiece thereon. The holding table 5 is configured from an annular supporting portion 51 and a holding portion 52 which covers an upper end of the supporting portion 51. The supporting portion 51 fits at a lower end portion thereof for rotation in the annular fitting groove 42 provided on the upper face of the second table 4. The holding portion 52 which configures the holding table 5 is formed, in the embodiment shown in the figures, at a central portion thereof for holding a workpiece thereon, from a glass plate 521, and an upper face of the glass plate 521 functions as a holding face for holding a workpiece thereon. On the upper face of the holding portion 52 configured in this manner which surrounds the glass plate 521, clamps 53 for fixing an annular frame hereinafter described are disposed as shown in FIG. 3.

Continuing the description with reference to FIG. 1, the processing apparatus includes rotating means 55 for rotating the holding table 5. This rotating means 55 is configured from a pulse motor 551 disposed on the second table 4, a pulley 552 mounted on a rotary shaft of the pulse motor 551, and an endless belt 553 extending around and between the pulley 552 and the annular supporting portion 51 of the holding table 5. In the rotating means 55 configured in this manner, the pulse motor 551 is driven to rotate the holding table 5 along the annular fitting groove 42 provided on the upper face of the second table 4 through the pulley 552 and the endless belt 553.

The processing apparatus includes an etching chamber 6 removably disposed on an outer peripheral portion of the holding portion 52, which configures the holding table 5, for accommodating a workpiece held on the holding face of the holding table 5 therein. The etching chamber 6 is configured from an annular side wall 61, and a top wall 62 which covers an upper end of the annular side wall 61, and an etching gas inlet port 621 and an etching gas outlet port 622 are provided on the top wall 62. Further, a central portion of the top wall 62 which configures the etching chamber 6 is formed from a transparent glass plate 623. A closed chamber 60 is formed as shown in FIG. 2 by mounting a lower end face of the annular side wall 61 of the etching chamber 6 configured in such a manner as described above on an outer peripheral portion of the holding portion 52 which configures the holding table 5 with suitable seal means interposed therebetween.

Continuing the description with reference to FIG. 1, the processing apparatus includes etching gas supplying means 7 for supplying etching gas to the etching chamber 6. The etching gas supplying means 7 is configured from an etching gas storage tank 71, a feeding pump 72 for feeding etching gas accommodated in the etching gas storage tank 71, an electromagnetic valve 74 disposed in a pipe 73 which connects the feeding pump 72 and the etching gas inlet port 621 of the etching chamber 6 to each other, and an electromagnetic valve 76 and a non-toxic filter 77 disposed in a pipe 75 connected to the etching gas outlet port 622 of the etching chamber 6. It is to be noted that, in the embodiment shown in FIG. 1, chlorine Cl₂ gas or chlorine trifluoride ClF₃ gas suitable for etching of silicon is accommodated in the etching gas storage tank 71 of the etching gas supplying means 7 described above.

Continuing the description with reference to FIGS. 2 and 3, at a central portion of the base 2, laser beam irradiation means 8 for irradiating a laser beam upon a workpiece held on the holding face of the holding table 5 is disposed. The laser beam irradiation means 8 includes laser beam oscillation means 81 for irradiating a laser beam of a wavelength which passes through the glass plate 521 of the holding table 5 and passes through a semiconductor wafer hereinafter described which is a workpiece, and a condenser 82 for condensing the laser beam oscillated from the laser beam oscillation means 81 and irradiating the condensed laser beam upon a workpiece held on the holding face of the holding table 5.

Continuing the description with reference to FIG. 1 again, the processing apparatus includes alignment means 9 disposed above a central portion of the etching chamber 6 as shown in FIG. 1. The alignment means 9 is disposed just above the condenser 82 which configures the laser beam irradiation means 8. The alignment means 9 is configured from optical means such as a microscope or a CCD camera and sends a picked up image signal to control means not shown.

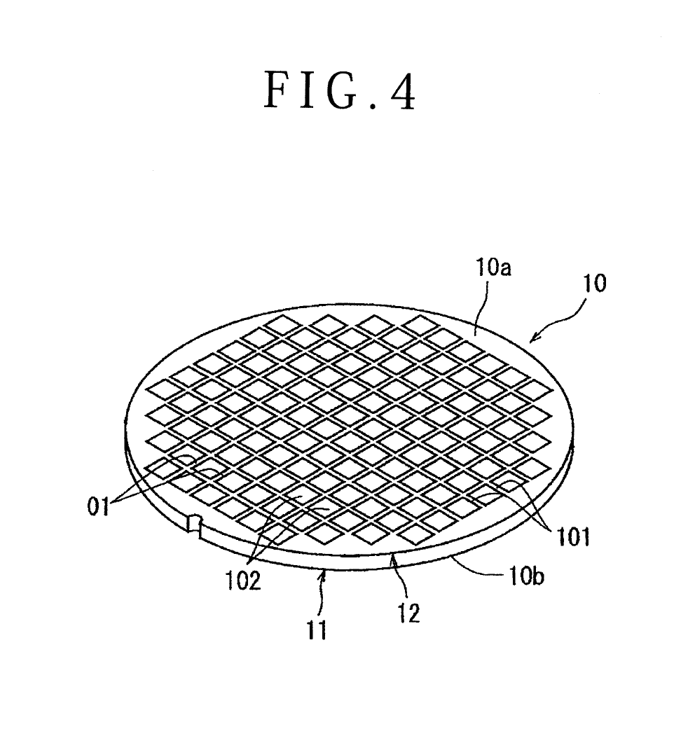

The processing apparatus is configured in such a manner as described above, and operation of the processing apparatus is described below. FIG. 4 shows a perspective view of a semiconductor wafer as a workpiece. The semiconductor wafer 10 shown in FIG. 4 has a plurality of regions partitioned by a plurality of streets 101 arrayed in a lattice shape on a front face 10a of a silicon substrate. A device 102 such as an IC or an LSI is formed in each of the partitioned regions. A method of forming dividing grooves along the streets 101 of the semiconductor wafer 10 configured in this manner is described.

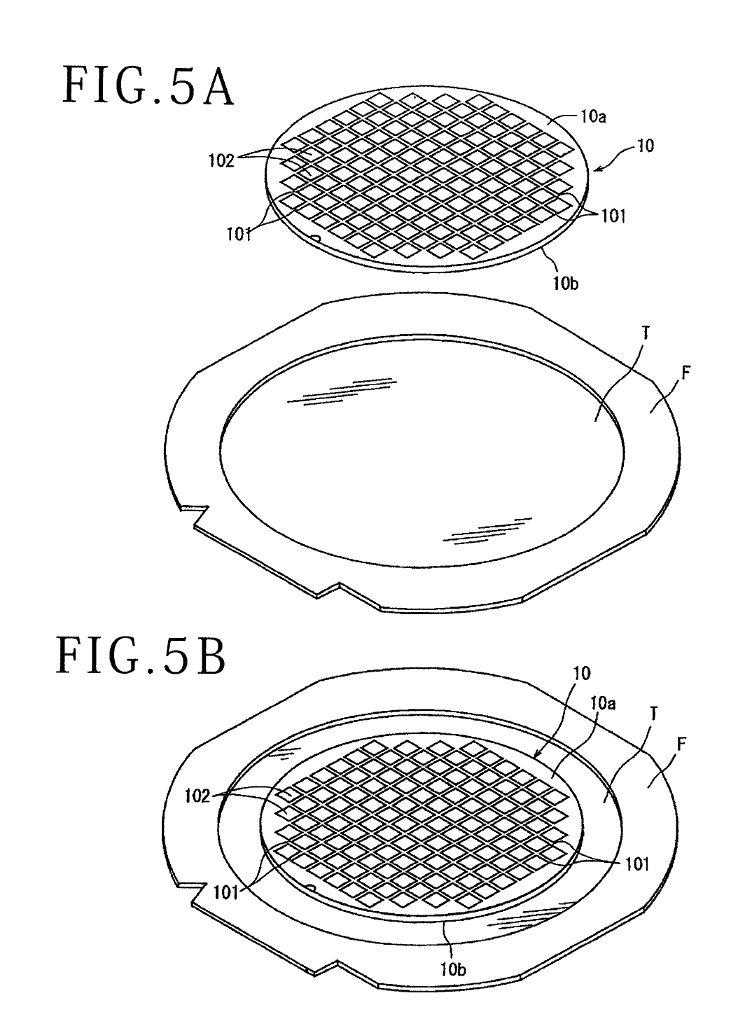

In order to form dividing grooves along the streets 101 on the semiconductor wafer 10 described above, the semiconductor wafer 10 is adhered to the surface of a protective tape T mounted on an annular frame F as shown in FIGS. 5A and 5B. At this time, the semiconductor wafer 10 is adhered on the rear face 10b side thereof to the protective tape T with the front face 10a directed upwardly. The semiconductor wafer 10 is supported on the annular frame F with the protective tape T interposed therebetween in this manner (wafer supporting step). It is to be noted that, in the present embodiment, the protective tape T is configured such that acrylic resin-based paste is applied by approximately 5 μm to the surface of a sheet-like substrate made of polyvinylchloride (PVC) of a thickness of 100 μm.

After the wafer supporting step described above is carried out, the etching chamber 6 is removed, and the semiconductor wafer 10 supported on the frame F with the protective tape T interposed therebetween is placed on the holding table 5. At this time, the semiconductor wafer 10 is positioned on the glass plate 521 which configures the holding portion 52 of the holding table 5. Then, the annular frame F on which the semiconductor wafer 10 is supported with the protective tape T interposed therebetween is fixed by the clamps 53. The semiconductor wafer 10 held on the holding table 5 with the protective tape T interposed therebetween in this manner is fixed with the front face 10a directed upwardly (wafer holding step).

After the wafer holding step is carried out in such a manner as described above, the etching chamber 6 is mounted at a predetermined position on the holding table 5. By mounting the etching chamber 6 at a predetermined position of the holding table 5 in this manner, the closed chamber 60 is formed in such a manner as shown in FIG. 2 (chamber sealing step).

Then, the alignment means 9 is rendered operative to execute an alignment operation of detecting a processing region, in which a dividing groove is to be formed, of the semiconductor wafer 10 held on the holding table 5 through the glass plate 623 provided on the top wall 62 of the etching chamber 6. In particular, the alignment means 9 and the control means not shown execute an image processing such as pattern matching for carrying out positioning of a street 101 formed in the first direction of the semiconductor wafer 10 and the condenser 82 of the laser beam irradiation means 8 which irradiates a laser beam along the street 101 thereby to carry out alignment of the laser beam irradiation position. At this time, if the street 101 does not extend in parallel to the processing feeding direction indicated by the arrow mark X, then the rotating means 55 is rendered operative to rotate the holding table 5 to carry out adjustment so that the street 101 may extend in parallel to the processing feeding direction indicated by the arrow mark X. Also for each of the streets 101 formed on the semiconductor wafer 10 and extending in the second direction perpendicular to the first direction, alignment of the laser beam irradiation position is carried out similarly (alignment step).

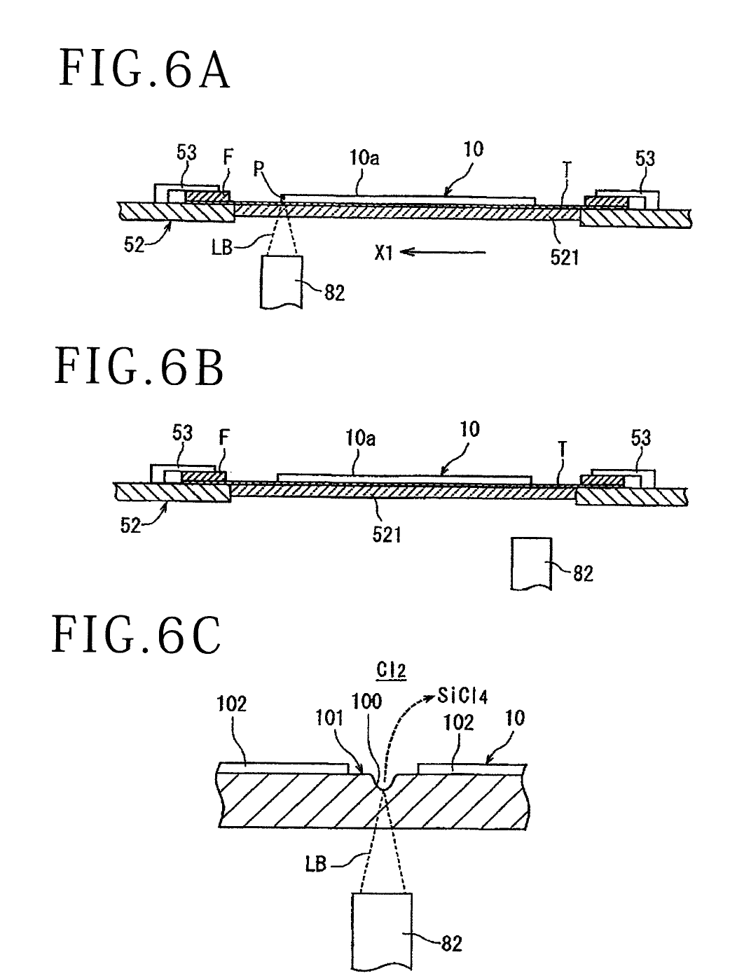

After the alignment step is carried out in such a manner as described above, the processing feeding means 35 and the indexing feeding means 45 are rendered operative to move the holding table 5 to a laser beam irradiation region at which the condenser 82 of the laser beam irradiation means 8 for irradiating a laser beam is positioned as shown in FIG. 6A and position one end (left end in FIG. 6A) of a predetermined street 101 of the semiconductor wafer 10 just above the condenser 82 of the laser beam irradiation means 8. Then, the focal point P of the laser beam irradiated from the condenser 82 is positioned at a position a little below the front face 10a (upper face) of the semiconductor wafer 10 (laser beam irradiation means positioning step). Then, the feeding pump 72 of the etching gas supplying means 7 is rendered operative to open the electromagnetic valve 74 so that etching gas such as chlorine (Cl₂) gas or chlorine trifluoride (ClF₃) gas accommodated in the etching gas storage tank 71 is introduced into the closed chamber 60 and open the electromagnetic valve 76 to exhaust gas containing the air in the closed chamber 60 through the non-toxic filter 77 (etching gas supplying step). In the state in which the etching gas such as chlorine (Cl₂) gas or chlorine trifluoride (ClF₃) gas is supplied into the closed chamber 60 in this manner, the laser beam irradiation means 8 is rendered operative to irradiate a laser beam LB of a wavelength having transparency through the glass plate 521 which configures the holding portion 52 of the holding table 5, the protective tape T and the silicon substrate which configures the semiconductor wafer 10 while the processing feeding means 35 is rendered operative to move the holding table 5 at a predetermined feeding speed in a direction indicated by the arrow mark X1 in FIG. 6A.

Then, if the irradiation position of the condenser 82 of the laser beam irradiation means 8 reaches the position at the other end of the street 101 as shown in FIG. 6B, then the irradiation of the laser beam is stopped and the movement of the holding table 5 is stopped. By positioning the focal point P of the laser beam LB irradiated from the condenser 82 to a position a little below the front face 10a (upper face) of the semiconductor wafer 10 and irradiating the laser beam LB in this manner, the region of the street 101 to be etched is excited to induce etching by the etching gas. As a result, where the etching gas is chlorine (Cl₂) gas as shown in FIG. 6C, the region to be etched of the street 101 is etched as SiCl₄ to form a dividing groove 100 (processing step). The dividing groove 100 formed by the etching in this manner is free from production of a crack or a modified layer. Further, since the region to be etched is excited by the laser beam, the region in which a groove is to be formed can be controlled readily.

The irradiation conditions of the laser beam at the processing step are set, for example, in the following manner.

(Irradiation conditions: 1)

Light source: YAG continuous wave laser

Wavelength: 1,064 nm

Average output power: 10 W

Condensed light spot diameter: φ1 μm

(Irradiation conditions: 2)

Light source: YAG pulsed laser

Wavelength: 1,064 nm

Repetition frequency: 10 kHz

Average output power: 1 W

Pulse width: 10 ns

Condensed light spot diameter: φ1 μm

After the processing step is carried out along the predetermined street 101 in such a manner as described above, the indexing feeding means 45 is rendered operative to feed the holding table 5 by a distance between the streets 101 formed on the semiconductor wafer 10 in the indexing feeding direction indicated by the arrow mark Y and then the processing process described above is carried out. After the processing is carried out along all of the streets 101 formed in the first direction in this manner, the rotating means 55 is rendered operative to rotate the holding table 5 by 90 degrees, and the processing step described above is executed along the streets 101 extending in the second direction perpendicular to the streets 101 formed in the first direction.

The semiconductor wafer 10 on which the dividing grooves 100 are formed along the streets 101 in such a manner as described above is transported to a dividing step of dividing the semiconductor wafer 10 into individual devices 102 along the streets 101 along which the dividing grooves 100 are formed.

While the present invention is described above based on the embodiment shown in the drawings, the present invention is not limited to the embodiment but various modifications are possible without departing from the spirit of the present invention. While the embodiment described hereinabove is directed to the example wherein the dividing grooves 100 are formed along the streets 101 of the semiconductor wafer 10, the present invention can be widely applied not only to grooving but also to other etching processes such as hole processing.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing method for a workpiece, comprising:
a holding step of holding a workpiece by a holding face of a holding table;
a workpiece accommodation step of accommodating the workpiece held on the holding table into an etching chamber;
an etching gas supplying step of supplying etching gas into the etching chamber after the workpiece accommodation step is carried out; and
an etching induction step of irradiating, while the etching gas is being supplied, a laser beam of a wavelength having a transparency through the holding table and the workpiece from the opposite side to the holding face of the holding table such that a focal point of the laser beam is positioned in the inside of a processing region of the workpiece to excite the processing region to induce etching.

2. The processing method according to claim 1, wherein the processing region is a grooving region, and the laser beam is irradiated along the grooving region with the focal point thereof positioned in the inside of the grooving region of the workpiece.

3. The processing method according to claim 1, wherein the workpiece is a silicon substrate, and the etching gas contains chlorine gas or chlorine trifluoride gas.

4. A processing apparatus for carrying out etching for a workpiece, comprising:
a holding table having a holding face for holding a workpiece;
an etching chamber for accommodating a workpiece held on the holding face of the holding table;
etching gas supplying means for supplying etching gas into the etching chamber;
laser beam irradiation means disposed on the opposite side to the holding face of the holding table for irradiating a laser beam toward the workpiece held on the holding face of the holding table; and
processing feeding means for feeding the holding table and the laser beam irradiation means relatively in a processing feeding direction for processing;
the laser beam irradiation means being rendered operative, while the etching gas supplying means is rendered operative to supply the etching gas into the etching chamber, to irradiate a laser beam of a wavelength having a transparency through the holding table and the workpiece such that a focal point of the laser beam is positioned in the inside of a processing region of the workpiece to excite the processing region to induce etching.
